(19) United States
(12) Patent Application Publication
(10) Pub. No.: US 2013/0083250 A1
(43) Pub. Date: Apr. 4, 2013

(54) TELEVISION RECEIVER AND ELECTRONIC DEVICE

(71) Applicants: Shinji HIRATOMO, Tokyo (JP); Ryosuke SAITO, Tokyo (JP)

(72) Inventors: Shinji HIRATOMO, Tokyo (JP); Ryosuke SAITO, Tokyo (JP)

(73) Assignee: KABUSHIKI KAISHA TOSHIBA, Tokyo (JP)

(21) Appl. No.: 13/552,385

(22) Filed: Jul. 18, 2012

(30) Foreign Application Priority Data
Sep. 30, 2011 (JP) 2011-218502

(51) Int. Cl. H05K 5/03; H04N 5/225

(52) U.S. Cl. 348/725; 361/679.01; 348/E05.026

(57) ABSTRACT

According to one embodiment, a television receiver includes a housing and a lid. The housing is configured to house therein a display device and at least a part of a connector. The housing includes an engaging portion and an opening through which the connector is exposed. The lid includes: a first portion covering the opening; a second portion located in the housing and configured to engage with the engaging portion to be prevented from moving toward outside of the housing; and a third portion extending between the first portion and the second portion, and configured to move between a first position inside the housing and a second position outside the housing through a gap between the connector and the housing.

### CROSS-REFERENCE TO RELATED APPLICATIONS

This application is based upon and claims the benefit of priority from Japanese Patent Application No. 2011-218502, filed on Sep. 30, 2011, the entire contents of which are incorporated herein by reference.

### FIELD

Embodiments described herein relate generally to a television receiver and an electronic device.

### BACKGROUND

Conventionally known are electronic devices that are each provided with a cover of a connector.

This type of electronic device has been desired to have a configuration with smaller number of components.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of a television receiver according to a first embodiment;

FIG. 2 is an exemplary side view of the television receiver in the first embodiment;

FIG. 3 is an exemplary perspective view of a part of the television receiver in a state in which a lid is closed, in the first embodiment;

FIG. 4 is an exemplary perspective view of the part of the television receiver in a state in which the lid is opened in the first embodiment;

FIG. 5 is an exemplary plan view of a part of an internal configuration of the television receiver in the first embodiment;

FIG. 6 is an exemplary perspective view of the part of the internal configuration of the television receiver in the first embodiment;

FIG. 7 is an exemplary perspective view of a part of a housing of the television receiver in the first embodiment;

FIG. 8 is an exemplary sectional view of the part of the internal configuration of the television receiver in the first embodiment;

FIG. 9 is an exemplary view of the internal configuration in a state in which the lid is opened from the state of FIG. 8, in the first embodiment;

FIG. 10 is an exemplary front view of an electronic device according to a second embodiment;

FIG. 11 is an exemplary rear view of the electronic device in the second embodiment;

FIG. 12 is an exemplary side view of the electronic device in the second embodiment;

FIG. 13 is an exemplary side view of the electronic device as viewed from a direction different from that of FIG. 12, in the second embodiment;

FIG. 14 is an exemplary side view of the electronic device as viewed from a direction different from those of FIGS. 12 and 13, in the second embodiment;

FIG. 15 is an exemplary side view of the electronic device as viewed from a direction different from those of FIGS. 12 to 14, in the second embodiment;

FIG. 16 is an exemplary exploded perspective view of the electronic device in the second embodiment;

FIG. 17 is an exemplary plan view of an internal configuration of the electronic device in the second embodiment;

FIG. 18 is an exemplary cross sectional view taken along XVIII-XVIII in FIG. 10, in the second embodiment;

FIG. 19 is an exemplary perspective view of a part of the electronic device in a state in which a lid is closed, in the second embodiment;

FIG. 20 is an exemplary perspective view of the part of the electronic device in a state in which the lid is open, in the second embodiment;

FIG. 21 is an exemplary cross sectional view of a part of the internal configuration of the electronic device in the second embodiment;

FIG. 22 is an exemplary view of the internal configuration in a state in which the lid is opened from the state of FIG. 21, in the second embodiment;

FIG. 23 is an exemplary plan view schematically illustrating a part of an electronic device in a state in which a lid is closed, according to a first modification;

FIG. 24 is an exemplary plan view schematically illustrating the part of the electronic device in a state in which the lid is open, in the first modification;

FIG. 25 is an exemplary cross sectional view taken along XXV-XXV in FIG. 23, in the first modification;

FIG. 26 is an exemplary plan view schematically illustrating a part of an electronic device in a state in which a lid is closed, according to a second modification;

FIG. 27 is an exemplary cross sectional view taken along XXVII-XXVII in FIG. 26, in the second modification; and

FIG. 28 is an exemplary sectional view schematically illustrating a part of an electronic device according to a third modification.

### DETAILED DESCRIPTION

In general, according to one embodiment, a television receiver comprises a housing and a lid. The housing is configured to house therein a display device and at least a part of a connector. The housing comprises an engaging portion and an opening through which the connector is exposed. The lid comprises a first portion, a second portion, and a third portion. The first portion covers the opening. The second portion is located in the housing and configured to engage with the engaging portion to be prevented from moving toward outside of the housing. The third portion extends between the first portion and the second portion, and is configured to move between a first position inside the housing and a second position outside the housing through a gap between the connector and the housing.

A plurality of exemplary embodiments described below comprise similar components. Accordingly, in the description below, common reference numerals are assigned to similar components, and duplicate description will be omitted. In the drawings, directions (X, Y, and Z directions) are indicated for convenience. The X direction is a lengthwise direction in the front view of a display screen of a television receiver; the Y direction is a traverse direction in the front view of the display screen; and the Z direction is a front-rear direction (depth direction, or thickness direction of housing) in the front view of the display screen. The X, Y, and Z directions are perpendicular to each other.

Although cases will be exemplified in which an electronic device is configured as a television receiver or as a personal computer of a tablet type or a slate type in the embodiments described below, electronic devices according to the present embodiments are not limited thereto. The electronic device in the present embodiments can be configured as various electronic devices, such as a personal computer of a notebook type or a desktop type, a smartphone, a smart TV, a smartbook, a mobile phone, a PDA (personal digital assistant), a video display device, and a videophone.

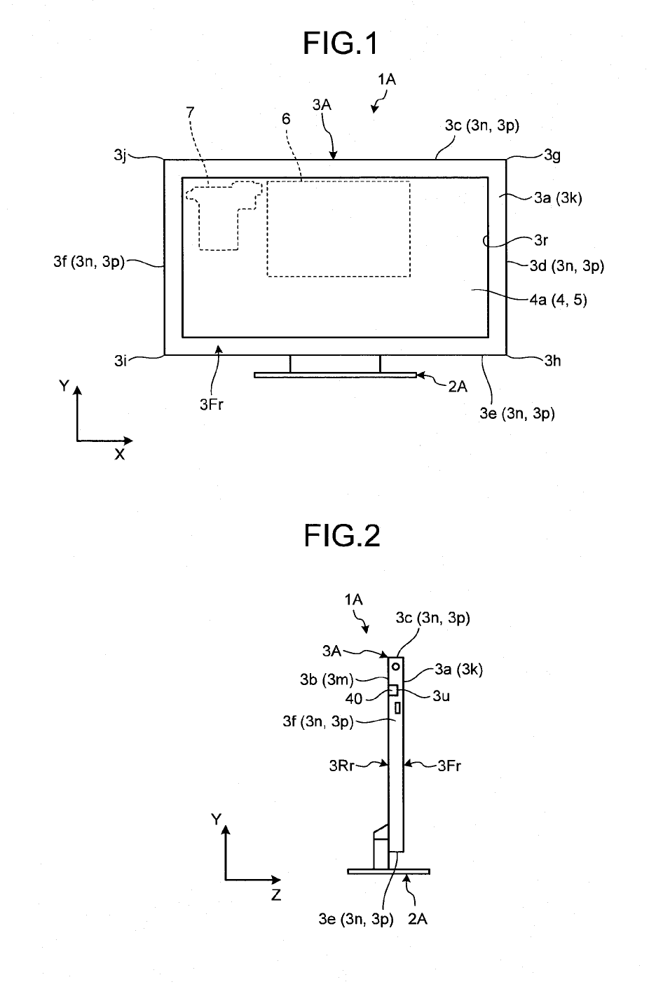

A television receiver 1A as an example of an electronic device according to a first embodiment comprises, as illustrated in FIGS. 1 and 2, a support (support portion, platform, or stand) 2A and a housing 3A. The support 2A is placed on a placement part (not illustrated) such as a desk, a rack, or a table, and supports the housing 3A. The support 2A may support the housing 3A in a fixed manner or in a movable (rotatable and/or slidable) manner. Modes of rotation of the housing 3A relative to the support 2A include, for example, tilting, swiveling, and pivoting.

The housing 3A is configured, as illustrated in FIG. 1, to have a rectangular shape (non-square rectangular shape as an example in the present embodiment) in the front view. The housing 3A is also configured, as illustrated in FIG. 2, to have a flat rectangular parallelepiped shape that is thin in the front-rear direction. The housing 3A comprises a front surface (front, surface, first surface, or first surface portion) 3a and a rear surface (rear, surface, second surface, or second surface portion) 3b on the opposite side of the front surface. The front surface 3a and the rear surface 3b are substantially alongside each other. The housing 3A also comprises, as illustrated in FIG. 1, four ends (sides, or edges) 3c to 3f and four corners (apexes, curves, or ends) 3g to 3j, in the front view. The ends 3c and 3e are examples of longer sides. The ends 3d and 3f are examples of shorter sides.

The housing 3A also comprises a wall (first wall portion, first portion, plate, frame, front wall, face wall, or top wall) 3k comprising the front surface 3a, and a wall (second wall portion, second portion, plate, rear wall, back wall, or bottom wall) 3m comprising the rear surface 3b. The walls 3k and 3m have each a rectangular shape (non-square rectangular shape as an example in the present embodiment). The housing 3A also comprises four walls (third wall portions, third portions, plates, side walls, end walls, standing walls, or bridging portions) 3n each comprising a side surface (surface, peripheral surface, or third surface) 3p provided in a bridging manner between the wall 3k and the wall 3m. The wall 3k is provided with an opening 3r having a rectangular shape as an example.

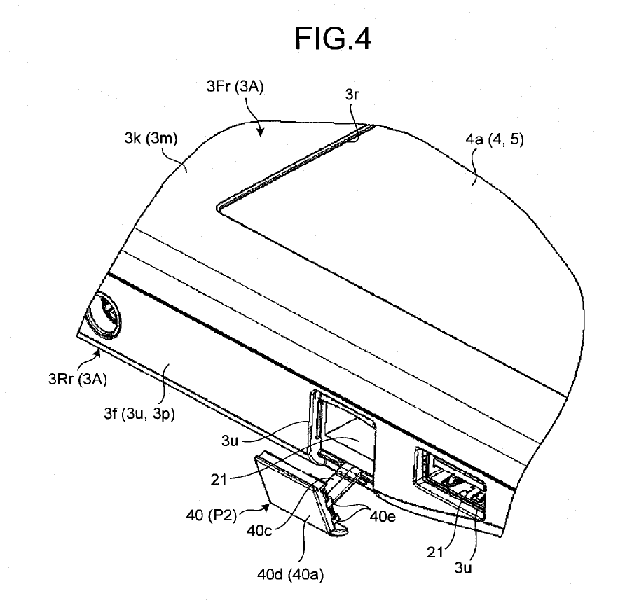

The housing 3A can be configured by combining a plurality of components (divided bodies and/or members). The housing 3A comprises, as an example, a first member (first portion, front member, or cover) 3Fr that comprises at least the wall 3k, and a second member (second portion, rear member, base, or bottom) 3Rr that comprises at least the wall 3m. The walls 3n can be comprised in at least one of the first member 3Fr and the second member 3Rr (for example, in the second member 3Rr). In addition to the first member 3Fr and the second member 3Rr, the housing 3A comprises a third member 3Md (third portion, intermediate member, dividing member, barrier member, wall member, interposed member, inner plate, middle plate, or middle frame; refer to FIG. 4) that is located between the first and the second members. In that case, the walls 3n can be comprised in the third member 3Md. The housing 3A can be composed of, for example, metallic material or synthetic resin material.

A display device (display portion, display, or panel) 4 is housed in the housing 3A. A display screen 4a of the display device 4 located on the side closer to the front surface 3a is exposed in front (outside) of the housing 3A via the opening 3r. Thus, a user can view the display screen 4a from the front side through the opening 3r. The display device 4 is configured to have a rectangular shape (non-square rectangular shape as an example in the present embodiment) in the front view. The display device 4 is also configured to have a flat rectangular parallelepiped shape that is thin in the front-rear direction. The display device 4 is, for example, a liquid crystal display (LCD) or an organic electro-luminescent display (OELD).

The display device 4 comprises, in front (on the face side, or on the side closer to the wall 3k) thereof, a transparent input operation panel (touchscreen, touch sensor, or operation surface as an example) 5 with a relatively thin rectangular shape. The input operation panel 5 covers the display screen 4a. An operator (such as the user) can execute input processing by performing operation such as touching, pressing, or dragging the input operation panel 5 with a finger or a stylus, or moving the finger or the stylus near the input operation panel 5. Light emitted from the display screen 4a of the display device 4 travels out from the opening 3r of the wall 3k to the front (outside) of the housing 3A through the input operation panel 5. The input operation panel 5 is an example of an input portion.

A plurality of boards 6 and 7 (circuit boards) are housed at the rear (on the back side, on the side behind, on the side closer to the wall 3m, or on the side opposite to the display screen 4a) of the display device 4 in the housing 3A. The boards 6 and 7 are located in positions different from each other. Both of the boards are provided alongside the display device 4. The boards 6 and 7 are also provided in a state separated from the walls 3k, 3m, and 3n, that is, in a state in which spaces are provided between themselves and the walls 3k, 3m, and 3n. The boards 6 and 7 are arranged along the display device 4, and preferably do not overlap each other in the thickness direction of the housing 3A. The boards 6 and 7 are fixed to the housing 3A with fixing devices such as screws.

A plurality of electronic components (components and/or devices, not illustrated) such as a central processing unit (CPU) are mounted on the board (first board, first circuit board, control board, or main board) 6 illustrated in FIG. 1. The electronic components comprise heat generating bodies. The electronic components (heat generating bodies) generating a large amount of heat can comprise a cooling mechanism (heat radiation portion or heat receiving portion not illustrated). At least a part of a control circuit (not illustrated) is composed of the board 6 and the electronic components. The control circuit can comprise, for example, a video signal processing circuit, a tuner module, a high-definition multimedia interface (HDMI) signal processor, an audio visual (AV) input terminal, a remote-control signal receiver, a controller, a selector, an on-screen display interface, memories (such as a read-only memory (ROM), a random access memory (RAM), and a hard disk drive (HDD)), and an audio signal processing circuit. The control circuit controls, for example, output of images (such as an moving image and a still image) on the display screen 4a of the display device 4, output of sounds from speakers (not illustrated), and emission of light from LEDs (light emitting diodes not illustrated). The display device 4, the speakers, and the LEDs are examples of output portions.

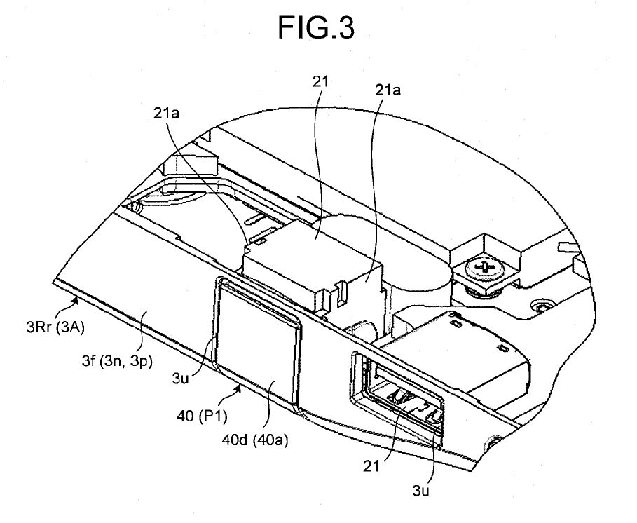

In the present embodiment, as an example, the wall 3n of the housing 3A is provided with openings 3u as illustrated in FIG. 3. The openings 3u can be provided, for example, as holes, through-holes, or cutouts in the wall 3n (side wall, vertical wall, or standing wall). In the present embodiment, as an example, the openings 3u are through-holes. Note that the openings 3u can be provided not only in the wall 3n but also in the wall 3k (front wall, face wall, upper wall, or top wall) and the wall 3m (rear wall, behind wall, back wall, lower wall, or bottom wall). As examples of functional components (components, electronic components, electric components, built-in components, or housed components), connectors 21 are exposed from the openings 3u. Other connectors are mechanically and electrically connected in a detachable manner to the connectors 21 through the openings 3u. The openings 3u are each covered by a lid 40 (cover, cap, covering portion, or closing portion). Note that, although the present embodiment exemplifies the configuration in which the lid 40 covers the connector 21 as an example, the lid 40 and the configuration related to the lid 40 according to the present embodiment can be applied in the same manner to a case in which the lid 40 covers a functional component other than the connector 21 and covers the opening 3u. The connector 21 is an example of a first component (component).

In the present embodiment, as an example, as illustrated in FIGS. 3 and 4, the lid 40 can move at least between a closed position P1 illustrated in FIG. 3 and an open position P2 illustrated in FIG. 4. In the present embodiment, as an example, the lid 40 is engaged with the housing 3A even in the open position P2. Consequently, the lid 40 is prevented from being lost by coming off from the housing 3A.

In the present embodiment, as an example, as illustrated in FIGS. 3 to 6, 8, and 9, the lid 40 comprises a first portion 40a, a second portion 40b, and a third portion 40c. The first portion 40a covers the opening 3u and the connector 21. The first portion 40a is configured to have a shape (rectangular shape as an example in the present embodiment) corresponding to the opening 3u. The first portion 40a is also configured to have a plate shape. A surface 40d (front face, outer surface, or top surface) of the first portion 40a and the side surface 3p of the housing 3A together forms a part of an outer surface of the housing 3A. The first portion 40a comprises, on peripheral edges thereof, claws 40e (refer to FIG. 4). The claws 40e engage with edges of the opening 3u of the wall 3n so that the lid 40 is supported in a closed state (refer to FIG. 3) by the housing 3A. In the present embodiment, as an example, the lid 40 is composed, at least partially (entirely as an example in the present embodiment), of a material (synthetic resin material as an example) with flexibility (elasticity, or softness). Thus, the lid 40 can be mounted to and removed from the housing 3A while involving an elastic deformation of the claws 40e or neighboring portions thereof. Note that elastically deformable portions can be provided to the housing 3A, and the lid 40 can be composed of a relatively hard material. In the present embodiment, the first portion 40a serves as a substantial lid (cover, cap, covering portion, or closing portion).

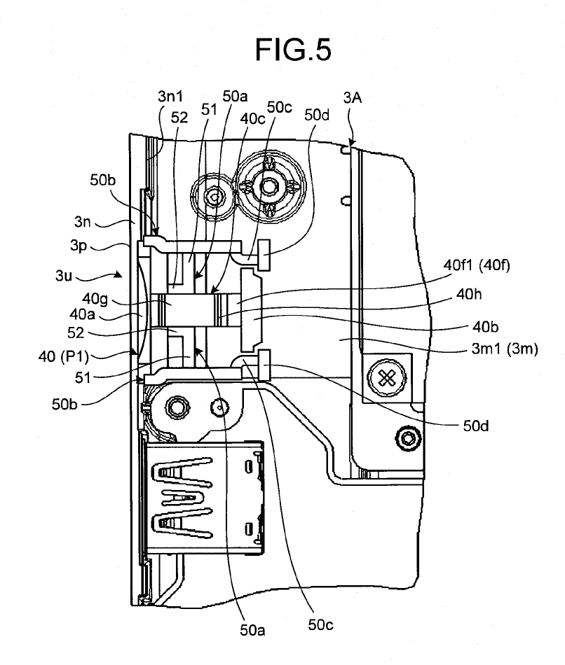

In the present embodiment, as an example, as illustrated in FIGS. 5, 6, and 8, the third portion 40c extends from the first portion 40a toward inside the housing 3A. The third portion 40c extends between the first portion 40a and the second portion 40b. The third portion 40c is connected to an end (side, edge, or peripheral edge) of the first portion 40a. The third portion 40c extends in a direction intersecting (in the present embodiment, as an example, perpendicular to) the surface 40d of the first portion 40a (refer to FIG. 3). The third portion 40c is formed in a strip shape (reed shape, flake shape, or rectangular plate shape). The third portion 40c has also a flat (flattened) shape (cross section) that is long in a direction along the wall 3m of the housing 3A. Consequently, the third portion 40c is relatively less likely to be bent in directions along the wall 3m.

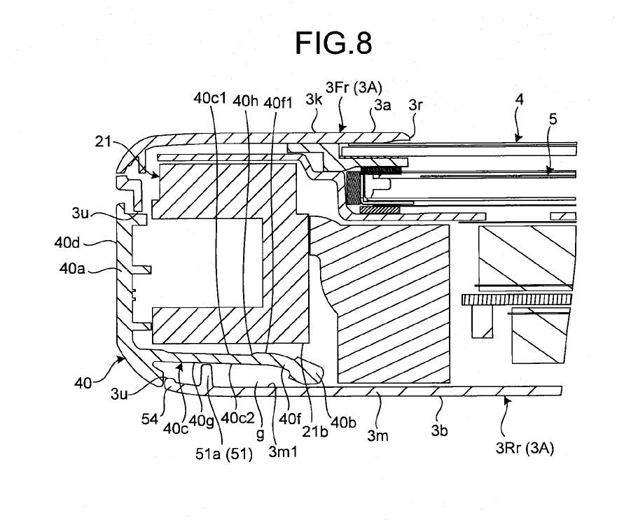

In the present embodiment, as an example, as illustrated in FIG. 8, the third portion 40c comprises a fourth portion 40f that is thicker than other portions of the third portion 40c. The fourth portion 40f is located relatively near (close to, or adjacent to) the second portion 40b. The third portion 40c also comprises a fifth portion 40g that is thinner than the fourth portion 40f between the first portion 40a and the fourth portion 40f. The third portion 40c can easily be bent at the fifth portion 40g. In the present embodiment, as an example, the fourth portion 40f comprises a projection 40f1 having a thickness increased in a direction away from the wall 3m of the housing 3A. In the present embodiment, as an example, the third portion 40c comprises, on a surface 40c1 thereof on the side away from the wall 3m of the housing 3A, a step 40h serving as a boundary between the fourth portion 40f and the fifth portion 40g. Consequently, according to the present embodiment, as an example, another surface 40c2 on the side closer to the wall 3m of the housing 3A can easily be in a relatively smooth form with little irregularity from the first portion 40a through to the second portion 40b.

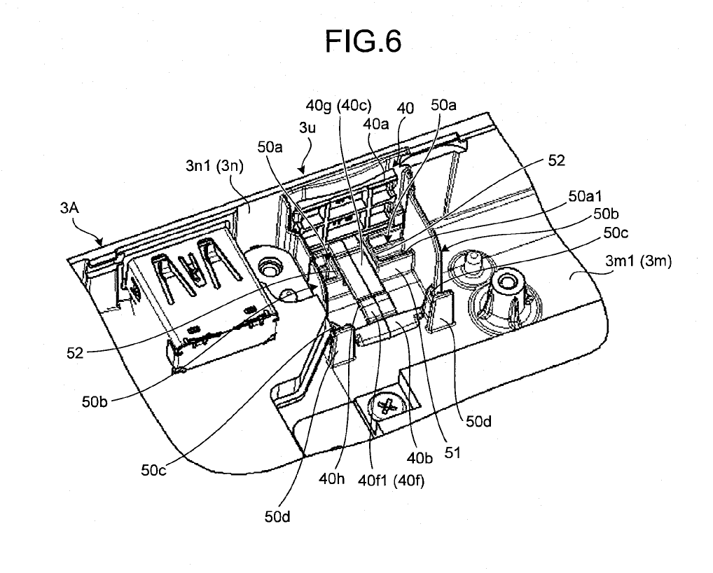

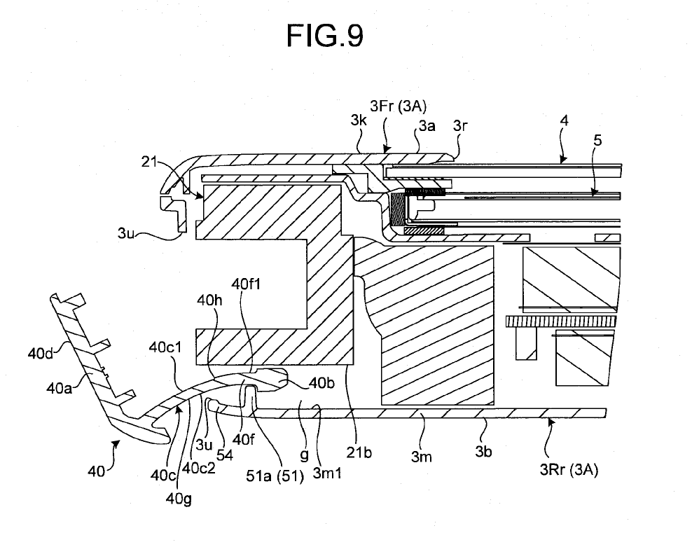

In the present embodiment, as an example, as illustrated in FIGS. 5, 6, 8, and 9, the lid 40 comprises the second portion 40b on a side of the third portion 40c opposite the first portion 40a. That is, the third portion 40c extends between the first portion 40a and the second portion 40b. As illustrated in FIGS. 5 and 6, the second portion 40b expands, at an end (tip) of the third portion 40c, toward both sides in a direction along the wall 3m of the housing 3A (in the width direction of the third portion 40c, or in the up-down direction in FIG. 5). As illustrated in FIGS. 8 and 9, the second portion 40b also expands, at the end (tip) of the third portion 40c, toward both sides in a direction coming close to the wall 3m of the housing 3A (in the thickness direction of the third portion 40c, or in the up-down direction in FIG. 8).

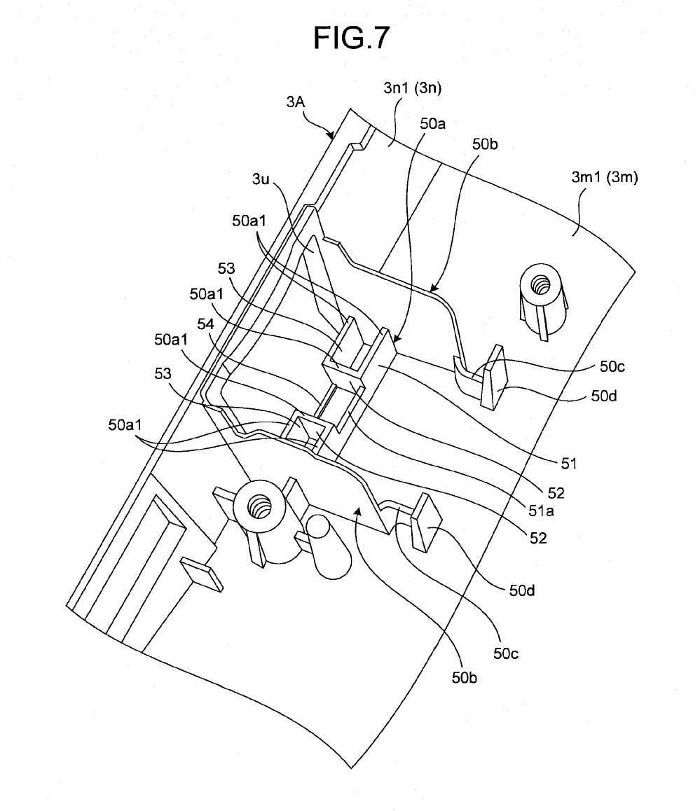

In the present embodiment, as an example, as illustrated in FIGS. 5 to 9, the wall 3m of the housing 3A comprises protrusions 50a and 50b (walls, or ribs). The protrusions 50a and 50b support the connector 21. The protrusion 50a (support, placing portion, support portion, or positioning portion) is lower than the protrusions 50b, and supports the connector 21 in a direction intersecting (in the present embodiment, as an example, perpendicular to) a surface 3m1 of the wall 3m. The protrusions 50b (supports, support portions, positioning portions, or guides) support the connector 21 in a direction along the surface 3m1. The protrusions 50a and 50b extend (project) from the wall 3m in the direction intersecting (in the present embodiment, as an example, perpendicular to) the wall 3m (surface 3m1). The protrusions 50b also extend (project) from the wall 3n in a direction intersecting the wall 3n (3n1) (in the present embodiment, as an example, perpendicular to the wall 3n and along the wall 3m). That is, the protrusions 50b are provided on (connected to, joined with, or extending between) both of the walls 3m and 3n. The protrusions 50a and 50b contribute to improvements in stiffness and strength of the housing 3A. In the present embodiment, as an example, two of the protrusions 50b are provided with a distance from each other, on both sides of the opening 3u interposed therebetween. The two protrusions 50b are provided alongside (in the present embodiment, as an example, in parallel with) each other. The connector 21 is supported by the two protrusions 50b in a state of being interposed therebetween. The connector 21 is also supported by a tip 50a1 (head, end, side, or apex; refer to FIG. 6) of the protrusion 50a and another component (member) (not illustrated) in a state of being interposed therebetween. As illustrated in FIG. 7, the two protrusions 50b comprise dents 50c at portions away from the wall 3n. The dents 50c dent along the wall 3m in a direction coming close to each other while denting in a direction coming close to the wall 3m. Bottoms of the dents 50c also support, in conjunction with the protrusion 50a, the connector 21 in the direction intersecting the wall 3m. Ends 50d of the protrusions 50b located farther away from the wall 3n than the dents 50c are extend alongside (in the present embodiment, as an example, in parallel with) the wall 3n. The connector 21 is supported by the wall 3n and the ends 50d in the direction intersecting (in the present embodiment, as an example, perpendicular to) the wall 3n (surface 3n1).

In the present embodiment, as an example, as illustrated in FIGS. 6 and 7, the protrusion 50a comprises a wall 51 along the wall 3n at a location away from the wall 3n. The wall 51 engages with the second portion 40b when the lid 40 is located at the open position P2 (that is, at a location outside the housing 3A), and thus, prevents the second portion 40b, that is, the lid 40 from moving away from the housing 3A beyond the open position P2. That is, the wall 51 is an example of an engaging portion. The second portion 40b engages with the wall 51 mainly at the portion expanding along the wall 3m and the portion expanding toward the wall 3m. The wall 51 and the second portion 40b are examples of engaging portions. The wall 51 is an example of a second support. The third portion 40c is an example of an extension, a joint, or a bridging portion that extends between the first portion 40a and the second portion 40b.

The protrusion 50a also comprises two walls 52 extending in a direction intersecting the wall 3n. The two walls 52 are provided alongside (in the present embodiment, as an example, in parallel with) each other. In the present embodiment, as an example, as illustrated in FIG. 6, the third portion 40c of the lid 40 is interposed between the two walls 52. Consequently, the two walls 52 guide the third portion 40c in the lengthwise direction thereof while preventing the third portion 40c from moving in the width direction thereof (in a direction along the wall 3n). Therefore, the two walls 52 are an example of a support, a guide, a rail portion, or a positioning portion for the third portion 40c.

The protrusion 50a also comprises walls 53 that are provided alongside the wall 51 and intersect the walls 52 at a location nearer the wall 3n than the wall 51 is. The walls 53 support the first portion 40a in a state in which the lid 40 is closed and located in the closed position P1. The walls 51, 52, and 53 project from the walls 3m and 3n of the housing 3A in a state of being connected to each other. With such a configuration, the protrusion 50a reinforces the housing 3A at a portion where the opening 3u is provided.

In the present embodiment, as an example, as illustrated in FIGS. 8 and 9, the protrusion 50a and the connector 21 provide a gap g through which the third portion 40c moves. In the gap g, the wall 3m is located on one side in the thickness direction of the third portion 40c (in the thickness direction of the housing 3A), and a surface 21b of the connector 21 is located on the other side of the third portion 40c. Also, in the gap g, the walls 52 are located on both sides in the width direction (in a direction along the wall 3n) of the third portion 40c. That is, in the present embodiment, as an example, the protrusion 50a and the connector 21 provided in the housing 3A determine a movable range of the third portion 40c accompanying the opening and closing of the lid 40. Consequently, according to the present embodiment, as an example, a configuration for guiding (supporting, or suppressing a movement of) the lid 40 (third portion 40c) can be obtained as a relatively simpler configuration than in the case of providing a component for guiding (supporting, or suppressing a movement of) the lid 40 (third portion 40c) separately from the connector 21.

In the present embodiment, as an example, the housing 3A comprises, in the gap g, the wall 51 and a wall 54 (protrusions) projecting from the wall 3m. The wall 51 is provided with a recess 51a between the two walls 52, 52, as can be understood from FIG. 7. In the gap g, the wall 51 projects from the wall 3m in a portion where the recess 51a is located. The wall 54 projects from the wall 3m on the outer side of the housing 3A (on the side closer to the wall 3n, or on an open end side of the opening 3u) relative to the wall 51. The walls 51 and 54 serve as supports (contact portions) for the third portion 40c that moves in accordance with the movement of the lid 40. Consequently, according to the present embodiment, as an example, the resistance of movement of the lid 40 may be reduced easily because a contact area is smaller than in the case in which the third portion 40c comes into contact with the surface 3m1 of the wall 3m. In addition, the wall 54 located close to the open end of the opening 3u is lower than the wall 51 located farther from the open end of the opening 3u. Therefore, according to the present embodiment, as an example, the third portion 40c, and consequently the first portion 40a, can move in a direction away from the center of the opening 3u (in the downward direction in FIGS. 8 and 9) as the third portion 40c moves toward the outside of the housing 3A. Hence, as an example, the first portion 40a is likely to open more widely. Therefore, as an example, it is easy to prevent the first portion 40a and the third portion 40c from interfering with another connector joined with (connected to, or electrically connected to) the connector 21. The wall 51 is an example of a third support (third contact portion, or third slide portion). The wall 54 is an example of a fourth support (fourth contact portion, or fourth slide portion).

In the present embodiment, as an example, as illustrated in FIGS. 8 and 9, the projection 40f1 of the fourth portion 40f projects (increases in thickness, or expands) toward a side opposite the walls 51 and 54, and the third portion 40c comprises, on the surface 40c1 thereof, the step 40h serving as the boundary between the fourth portion 40f and the fifth portion 40g. Consequently, according to the present embodiment, as an example, the surface 40c2 of the third portion 40c on the side closer to the wall 3m of the housing 3A can easily be formed relatively smoothly with little irregularity from the first portion 40a through to the second portion 40b.

In the present embodiment, as an example, the walls 52 are located relatively near (close to, or adjacent to) the wall 51, and the fourth portion 40f is located relatively near (close to, or adjacent to) the second portion 40b. Consequently, according to the present embodiment, as an example, the fourth portion 40f faces the walls 52 when the lid 40 is opened and located in the open position P2. Hence, as an example, the walls 52 easily support the lid 40 in a more reliable (tighter) manner. Therefore, as an example, the lid 40 is less likely to come off from the housing 3A.

As described above, in the present embodiment, the third portion 40c of the lid 40 is located in the gap between the connector 21 and the wall 3m. Consequently, according to the present embodiment, as an example, the connector 21 can be used as a component for suppressing the movement of the third portion 40c or for guiding the third portion 40c. Therefore, as an example, the configuration can easily be more simplified than in the case of separately providing a component for suppressing the movement of the third portion 40c or for guiding the third portion 40c.

In the present embodiment, as an example, the walls 52 not only support the connector 21, but also suppress the movement of the third portion 40c or guide the third portion 40c. Consequently, according to the present embodiment, as an example, the configuration can easily be more simplified than a configuration in which one portion supports the connector 21 while another portion suppresses the movement of the third portion 40c or guides the third portion 40c.

In the present embodiment, as an example, the walls 52 are located relatively near the second portion 40b. Therefore, as an example, the housing 3A can easily have higher stiffness. Also, as an example, the lid 40 is less likely to come off from the housing 3A when the third portion 40c comprises the fourth portion 40f relatively near the second portion 40b.

In the present embodiment, as an example, the wall 51 not only supports the connector 21, but also engages with the second portion 40b. Consequently, according to the present embodiment, as an example, the configuration can easily be more simplified than a configuration in which one portion supports the connector 21 while another portion engages with the second portion 40b.

In the present embodiment, as an example, the third portion 40c comprises, relatively near the second portion 40b, the fourth portion 40f that is thicker than the other portions. Consequently, according to the present embodiment, as an example, the second portion 40b engages with the wall 51 in a more reliable (tighter) manner. Therefore, as an example, the lid 40 is less likely to come off from the housing 3A.

In the present embodiment, as an example, the third portion 40c comprises the fifth portion 40g. Consequently, according to the present embodiment, as an example, the third portion 40c can be bent more easily. Therefore, as an example, the first member 40a is likely to open more widely.

In the present embodiment, as an example, the projection 40f1 of the fourth portion 40f projects toward a side opposite the walls 51 and 54. Consequently, according to the present embodiment, as an example, the third portion 40c is likely to move more smoothly.

In the present embodiment, as an example, the wall 54 projects lower than the wall 51. Consequently, according to the present embodiment, as an example, the third portion 40c can be bent more easily. Therefore, as an example, the first member 40a is likely to open more widely.

An electronic device 1B according to a second embodiment is, for example, a personal computer that is, for example, of a so-called slate type, of a tablet type, or provided with a display device having a virtual keyboard function, a television receiver, a smartphone, a smartbook, a mobile phone, or a PDA.

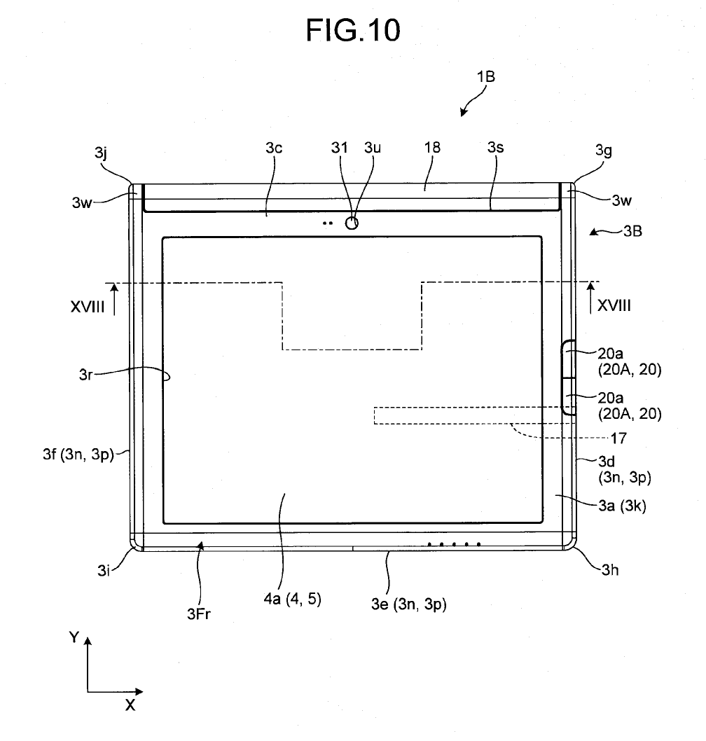

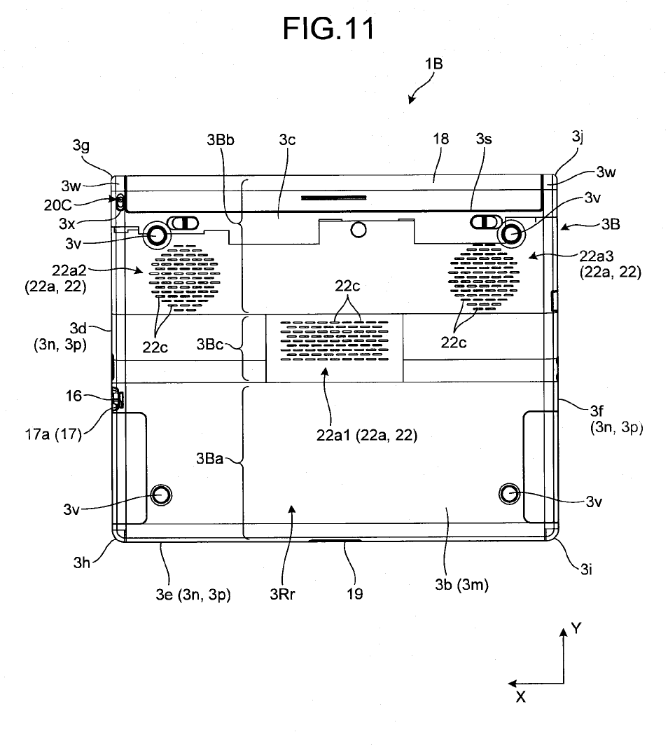

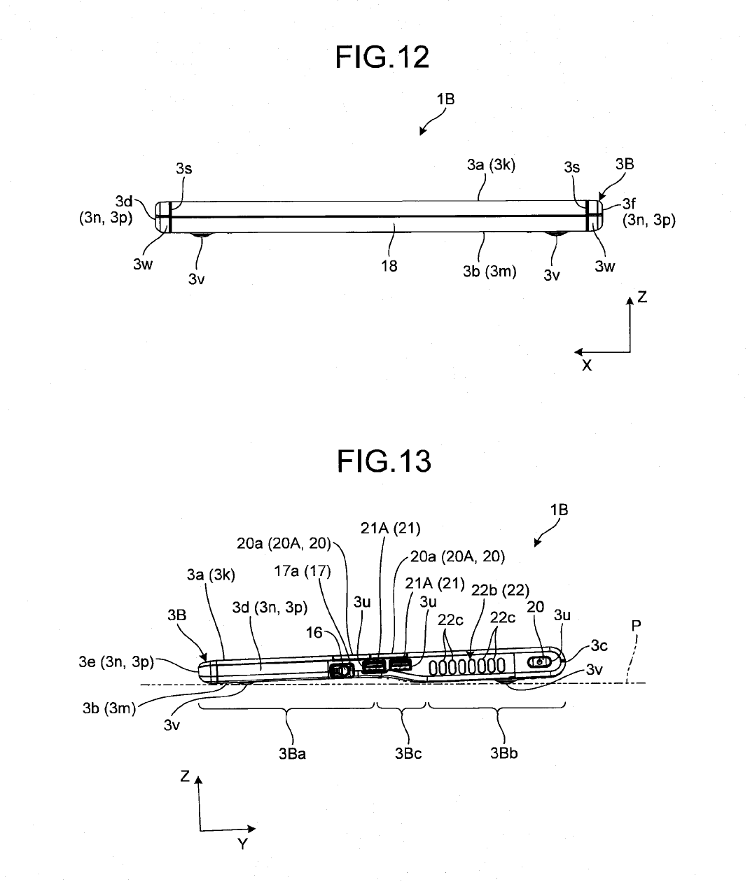

A housing 3B of the electronic device 1B is configured, as illustrated in FIGS. 10 and 11, to have a rectangular shape (non-square rectangular shape as an example in the present embodiment) in the front and rear views. The housing 3B is also configured, as illustrated in FIGS. 12 to 15, to have a flat rectangular cuboid shape that is thin in the front-rear direction. The housing 3B comprises the front surface (front, surface, first surface, or first surface portion) 3a and the rear surface (rear, surface, second surface, or second surface portion) 3b on the opposite side of the front surface. The front surface 3a and the rear surface 3b are substantially alongside each other. The housing 3B also comprises, as illustrated in FIGS. 10 to 11, the four ends (sides, or edges) 3c to 3f and the four corners (apexes, curves, or ends) 3g to 3j, in the front view. The ends 3c and 3e are examples of longer sides. The ends 3d and 3f are examples of shorter sides.

The housing 3B also comprises the wall (first wall portion, first portion, plate, frame, front wall, face wall, or top wall) 3k comprising the front surface 3a, and the wall (second wall portion, second portion, plate, rear wall, back wall, or bottom wall) 3m comprising the rear surface 3b. The walls 3k and 3m have each a rectangular shape (non-square rectangular shape as an example in the present embodiment). The housing 3B also comprises the four walls (third wall portions, third portions, plates, side walls, end walls, standing walls, or bridging portions) 3n each comprising the side surface (surface, peripheral surface, or third surface) 3p provided in a bridging manner between the wall 3k and the wall 3m. The wall 3k is provided with the opening 3r having a rectangular shape as an example.

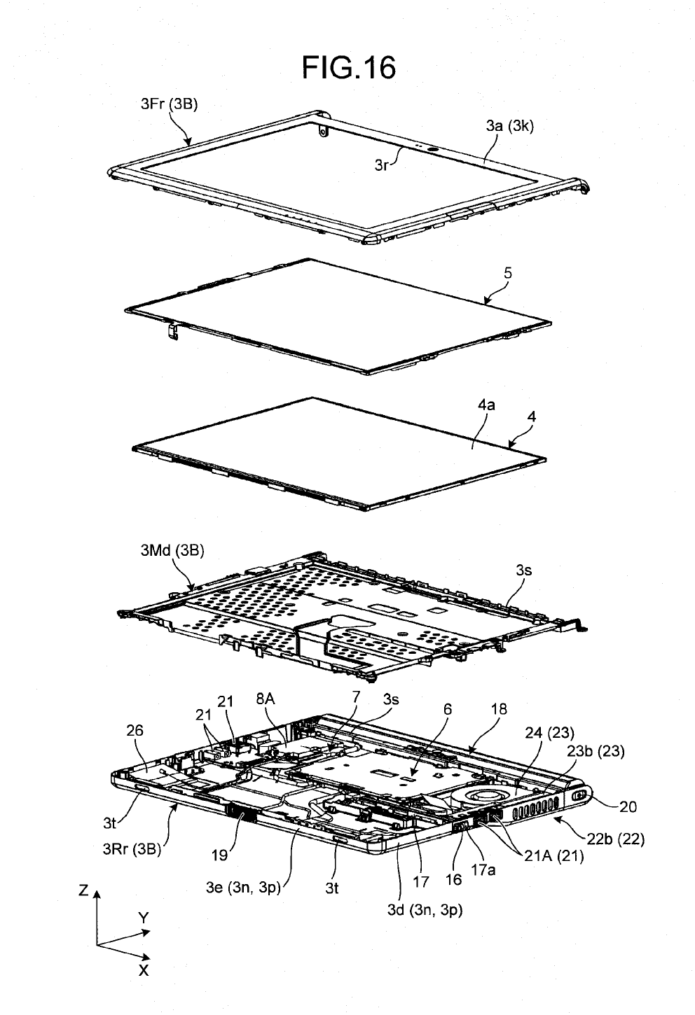

The housing 3B can be configured by combining a plurality of components (divided bodies). The housing 3B comprises, as an example, the first member (first portion, front member, or cover) 3Fr that comprises at least the wall 3k, and the second member (second portion, rear member, base, or bottom) 3Rr that comprises at least the wall 3m. The walls 3n are comprised in at least one of the first member 3Fr and the second member 3Rr (for example, in the second member 3Rr). In the present embodiment, as illustrated in FIG. 16, in addition to the first member 3Fr and the second member 3Rr, the housing 3B comprises the third member 3Md (third portion, intermediate member, dividing member, barrier member, wall member, interposed member, inner plate, middle plate, or middle frame) that is located between the first and the second members. A part of the walls 3n can be comprised in the third member 3Md. The housing 3B can be composed of, for example, metallic material or synthetic resin material. As an example, the second member 3Rr and the third member 3Md can be composed of, for example, metallic material such as magnesium alloy, and the first member 3Fr can be composed of synthetic resin material having lower stiffness than those of the second member 3Rr and the third member 3Md. Note that the first member 3Fr, the second member 3Rr, and the third member 3Md can comprise walls (protrusions, or projecting walls) such as ribs. The walls increase the stiffness of the housing 3B. The third member 3Md can also be provided with openings such as through-holes. The housing 3B can be configured to be lighter in weight by the openings.

In the present embodiment, as illustrated in FIGS. 13 and 15, as an example, a first portion 3Ba located on the lower side or front side (side close to the user) in the state in which the electronic device 1B is used with the longer side thereof oriented sideways has a thickness smaller than that of a second portion 3Bb located on the upper side or rear side (side away from the user) in the same state. Therefore, in the state in which the electronic device 1B is used while being placed on a placing surface P such as a desk, the front surface 3a of the housing 3B and the display screen 4a increase in height from the placing surface Pas a position thereof changes from the front side (lower side) to the rear side (upper side). Consequently, according to the present embodiment, as an example, there is an advantage that the display screen 4a is placed in a so-called tilted state for the user positioned on the left side of FIG. 13 and on the right side of FIG. 15 relative to the electronic device 1B, and thus, the user can easily view the display screen 4a.

An orientation of an image output on the display screen 4a in use can be changed depending on an attitude of the housing 3B (electronic device 1B). For example, the control circuit (not illustrated) comprised in the housing 3B can change an orientation, a size, and so on of the image output on the display screen 4a depending on a detection result of a sensor (such as a gyro sensor or an acceleration sensor) or the like comprised in the housing 3B. The control circuit can also limit attitudes of the image to several types. Specifically, for example, when the end 3c of the housing 3B is located above the end 3e thereof (first attitude), the control circuit can display, on the display screen 4a, an image with the top thereof on the side of the end 3c, whereas when the end 3d is located above the end 3f (second attitude), the control circuit can display, on the display screen 4a, the image with the top thereof on the side of the end 3d. Thus, when the attitude of the housing 3B is changed from a previous attitude to the first attitude or the second attitude, the control circuit switches the image on the display screen 4a to the image corresponding to the new attitude. However, when the attitude of the housing 3B is changed from the previous attitude to an attitude other than the first attitude and the second attitude (that is, in this example, to an attitude in which the end 3e is located above the end 3c, or to an attitude in which the end 3f is located above the end 3d), the control circuit does not switch the image on the display screen 4a. The control as described above can limit the attitude of the electronic device 1B while in use by the user.

The housing 3B comprises a component housing 17 that houses a component 16 in a removable manner. In the present embodiment, as an example, an opening 17a of the component housing 17 opens at the end 3d. The opening 17a is provided in the end 3d which is located on the upper side in some in-use attitude (in the above-described example, the first attitude or the second attitude), and which is not located on the lower side in a non-use attitude. With such a configuration, the opening 17a is located on the upper side in an in-use attitude. Consequently, as an example, it is easy to prevent the component 16 from coming off from the component housing 17 by an action of gravity. Specifically, the component 16 is, for example, a stylus, a stylus pen, or a pen.

As illustrated in FIG. 10, in the present embodiment, a battery 18 and the display device 4 are arranged side by side in a direction perpendicular to the thickness direction of the housing 3B (in a direction along the front surface 3a or the rear surface 3b, that is, in the X or Y direction; in the present embodiment, as an example, in the Y direction) without overlapping each other in the thickness direction. Consequently, as an example, the housing 3B can be configured to be thinner than in the case in which the battery 18 and the display device 4 overlap each other in the thickness direction of the housing 3B. Alternatively, as an example, compared with the case in which the battery 18 and the display device 4 overlap each other in the thickness direction of the housing 3B, the battery 18 can easily be thicker, and consequently, a capacity per unit volume of the battery 18 can easily be increased. As illustrated in FIGS. 13 and 15, in the present embodiment, the housing 3B comprises the thin first portion 3Ba and the thick second portion 3Bb. A battery housing (battery support) 3s housing the battery 18 is provided at the end 3c of the thick second portion 3Bb. Therefore, as an example, compared with the case in which the battery housing 3s is provided at the first portion 3Ba, the battery 18 can easily be thick, and consequently, a charging capacity per unit volume of the battery 18 can easily be increased.

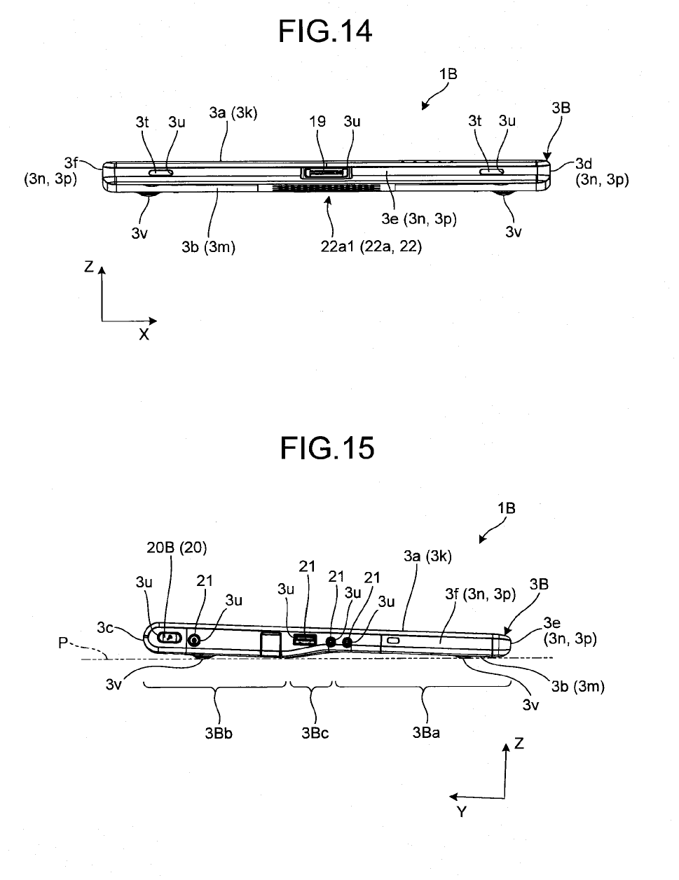

In the present embodiment, the end 3e on the opposite side of the end 3c provided with the battery housing 3s is supported by a docking station (another electronic device, not illustrated). Consequently, as an example, the operator (such as the user) can mount and remove the battery 18 to and from the housing 3B in the state in which the electronic device 1B is supported by the docking station. The end 3e comprises, as illustrated in FIG. 14, connector 19 that is connected to a connector (not illustrated) of the docking station. Consequently, as an example, the battery housing 3s and the connector 19 can easily be provided at the housing 3B without interfering each other. Terminals 3t are exposed at the end 3e. The connector 19 and the terminals 3t are exposed via the openings 3u provided in the wall 3n at the end 3e.

A portion hidden by the battery 18 in the battery housing 3s comprises a joint portion of two or more (two or three) of any of the first member 3Fr, the second member 3Rr, and the third member 3Md of the housing 3B. In the joint portion, for example, screws as examples of connecting devices connect the first member 3Fr with the third member 3Md or the second member 3Rr. When disassembling the housing 3B, the operator (such as the user) removes the screws first, and then, separates and spaces apart the first member 3Fr from the third member 3Md or the second member 3Rr at least locally at this portion. Thereafter, the operator releases the connection of the elastic joint portion (engaging portion, connecting portion, or portion engaged by claws and edges of holes as an example; not illustrated) between the first member 3Fr and the third member 3Md or the second member 3Rr while, for example, elastically deforming the first member 3Fr by applying a force to the portion spaced apart. Thus, the operator removes the first member 3Fr from the third member 3Md or the second member 3Rr. A plurality of such joint portions (engaging portions, or connecting portions) between the first member 3Fr and the third member 3Md or the second member 3Rr are provided along the outer circumference of the first member 3Fr. All of a plurality of screws (not illustrated) serving as connecting devices for connecting the second member 3Rr with the third member 3Md are covered by the first member 3Fr. Consequently, the operator can remove those screws by removing the first member 3Fr from the third member 3Md or the second member 3Rr, and thus, can separate the second member 3Rr from the third member 3Md. With such a configuration, the housing 3B can be disassembled smoothly once the battery 18 has been removed from the battery housing 3s. That is, the housing 3B can be prevented from being disassembled in the state in which the battery 18 is mounted in the battery housing 3s.

In the present embodiment, the second member 3Rr and the third member 3Md stretch out up to the battery housing 3s, and constitute a part of the end 3c (wall 3n, or side surface 3p). Consequently, as an example, the stiffness of the housing 3B can be made higher. Because the stiffness of the battery housing 3s is made higher, it is far easier to suppress vibration and displacement of the battery 18, as an example.

As illustrated in FIGS. 10 to 15, the front surface 3a and the side surfaces 3p of the housing 3B comprise operation portions 20 and the connectors 21. The operation portions 20 can be, for example, push buttons, push switches, slide switches, and pointing devices. The connectors 21 are, for example, a connector for a power cable, USB connectors, connectors for an earphone and a microphone. The operation portions 20 and the connectors 21 are exposed via the openings 3u provided in the walls 3k and 3n of the housing 3B. The front surface 3a can comprise a camera (camera module, or image-taking device) 31.

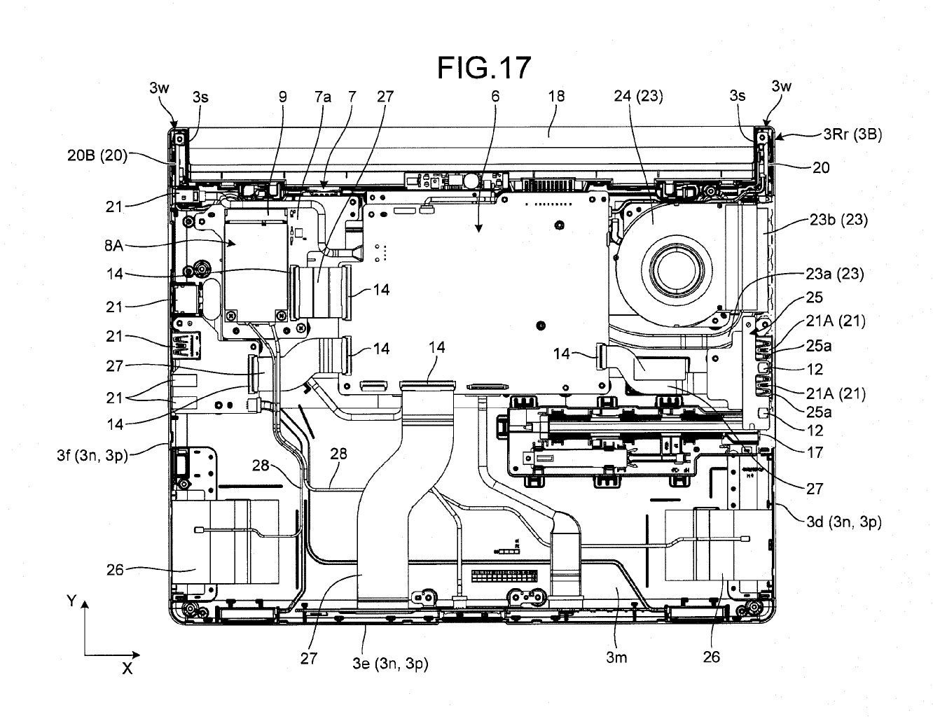

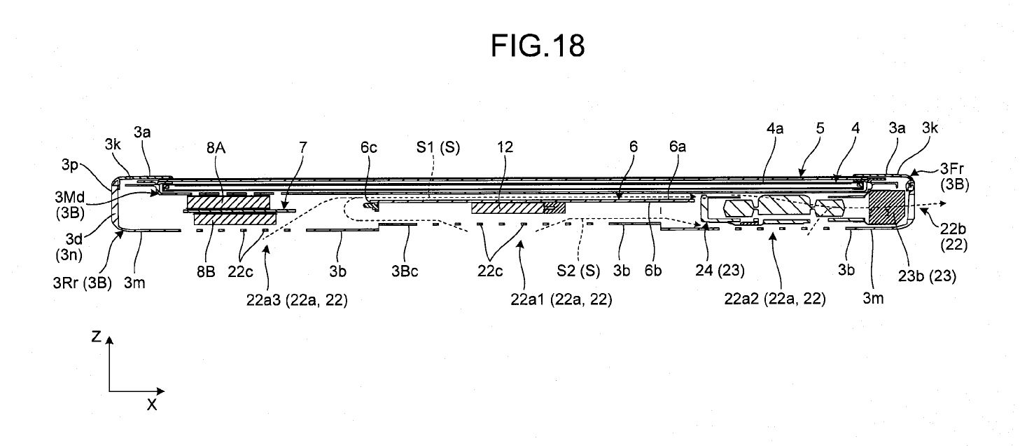

As illustrated in FIGS. 11 and 13, the rear surface 3b and the side surface 3p of the housing 3B are provided with vent holes 22 that introduce or exhaust air used for, for example, cooling electronic components 12 (refer to, for example, FIG. 18). In the present embodiment, as an example, the rear surface 3b (wall 3m) is provided with introduction ports 22a that introduce air, and the side surface 3p (wall 3n, end 3d) is provided with an exhaust port 22b that exhausts air. In the present embodiment, the introduction ports 22a and the exhaust port 22b are provided as portions in which a plurality of small openings 22c provided in the walls 3m and 3n are grouped together. Note that the rear surface 3b comprises protrusions 3v. Therefore, the introduction ports 22a are not closed even in the state in which the rear surface 3b is placed on the placing surface P, as illustrated in FIGS. 13 and 15. In the present embodiment, a boundary portion between the thin first portion 3Ba and the thick second portion 3Bb of the housing 3B comprises a slope portion 3Bc. In addition, as illustrated in FIG. 11, one introduction port 22a1 of the introduction ports 22a is provided at the rear surface 3b at the slope portion 3Bc. As illustrated in FIGS. 13 and 15, the distance between the slope portion 3Bc and the placing surface P is greater than the distance between the other portions and the placing surface P. Therefore, the introduction port 22a1 provided at the slope portion 3Bc can easily have reduced air-flow resistance, and thus, cooling efficiency can easily be increased. Moreover, in the present embodiment, the introduction ports 22a are provided in plurality. Therefore, as an example, even if one of the introduction ports 22a is closed due to some cause, the other introduction ports 22a can introduce air flows into the housing 3B, and thus, the cooling performance is hardly impaired. The inside of the housing 3B may be cooled by a cooling mechanism 23 (refer to, for example, FIG. 17), or by natural cooling (convection cooling).

As illustrated in FIG. 16, also in the present embodiment, as an example, the housing 3B houses the display device (display portion, display, or panel) 4 between the first member 3Fr and the third member 3Md. The display screen 4a of the display device 4 located on the side closer to the front surface 3a is exposed in front (outside) of the housing 3B via the opening 3r. Thus, the user can view the display screen 4a from the front side through the opening 3r. The display device 4 is configured to have a rectangular shape (non-square rectangular shape as an example in the present embodiment) in the front view. The display device 4 is also configured to have a flat rectangular cuboid shape that is thin in the front-rear direction. The display device 4 is, for example, a liquid crystal display (LCD) or an organic electro-luminescent display (OELD).

The display device 4 comprises, in front (on the face side, or on the side closer to the wall 3k) thereof, the transparent input operation panel (touchscreen, touch sensor, or operation surface as an example) 5 having a relatively thin rectangular shape. The input operation panel 5 covers the display screen 4a. The operator (such as the user) can execute input processing by performing operation such as touching, pressing, or dragging the input operation panel 5 with a finger or the component 16 (stylus), or moving the finger or the stylus near the input operation panel 5. Light emitted from the display screen 4a of the display device 4 goes out from the opening 3r of the wall 3k to the front (outside) of the housing 3B through the input operation panel 5. The input operation panel 5 is an example of an input portion.

As illustrated in, for example, FIGS. 16 and 17, a plurality of boards 6, 7, and 25 are housed at the rear (on the back side, on the side behind, on the side closer to the wall 3m, or on the side opposite to the display screen 4a) of the display device 4 (in the present embodiment, as an example, between the second member 3Rr and the third member 3Md) in the housing 3B. The boards 6, 7, and 25 are located in positions different from each other. All of the boards are provided alongside the display device 4. The boards 6, 7, and 25 are also provided in a state separated from the walls 3k, 3m, and 3n, that is, in the state in which spaces are provided between themselves and the walls 3k, 3m, and 3n. The boards 6, 7, and 25 are arranged along the display device 4, and are preferably arranged so as not to overlap each other in the thickness direction of the housing 3B. The boards 6, 7, and 25 are fixed to the housing 3B with fixing devices such as screws.

The board (first board, first circuit board, control board, or main board) 6 can be mounted with the plurality of electronic components 12 (refer to, for example, FIG. 18, which illustrates only some of the components), such as a central processing unit (CPU), a graphic controller, power supply circuit components, a platform controller hub (PCH), a memory slot connector, an LCD connector, an input/output (I/O) connector, a power coil, devices, and connectors. The electronic components 12 comprise heat generating bodies. The electronic components (heat generating bodies) 12 generating a large amount of heat can comprise the cooling mechanism 23. The cooling mechanism 23 comprises, for example, a heat sink (heat receiving portion, not illustrated), a heat pipe 23a, a heat radiation portion 23b, and a fan 24. At least apart of the control circuit (not illustrated) is composed of the board 6 and the electronic components 12. The control circuit can comprise, for example, a video signal processing circuit, a tuner module, a high-definition multimedia interface (HDMI) signal processor, an audio visual (AV) input terminal, a remote-control signal receiver, a controller, a selector, an on-screen display interface, memories (such as a read-only memory (ROM), a random access memory (RAM), and a hard disk drive (HDD), and an audio signal processing circuit. The control circuit controls, for example, output of images (such as an animation and a still image) on the display screen 4a of the display device 4, output of sounds from speakers (not illustrated), and emission of light from light emitting diodes (LEDs) not illustrated. The display device 4, the speakers, and the LEDs are examples of output portions.

The board 7, and modules 8A and 8B have the same configurations as those of the first embodiment described above. Also in the present embodiment, a first surface 7a and the module 8A of the board 7 are located on the side closer to the display device 4 while a second surface 7b and the module 8B of the board 7 are located on the side away from the display device 4. The first surface 7a, the second surface 7b, and the modules 8A and 8B are arranged along the display device 4. The board 25 comprises the electronic components 12. The housing 3B houses flexible cables 27. The flexible cables 27 electrically connect the boards 6, 7, and 25, the display device 4, and the connector 19 to each other. The flexible cables 27 are electrically connected to corresponding connectors 14. The flexible cables 27 are, for example, flexible printed wiring boards and flat cables.

As illustrated in FIG. 17, the housing 3B houses a plurality of antennas 26. In the present embodiment, the plurality of antennas 26 connected to one communication module (for example, the module 8B) are arranged in a mutually spaced manner. In the present embodiment, as an example, one of the antennas 26 is arranged near the end 3d and the end 3e (near the corner 3h) of the housing 3B while the other of the antennas 26 is arranged near the end 3e and the end 3f (near the corner 3i) of the housing 3B. With this arrangement, as an example, a spatial diversity of the antennas 26 can be formed. The antennas 26 are electrically connected to the module 8B via cables 28. Note that the plurality of antennas 26, 26 can be used for separate functions. For example, one of the antennas 26 can be used for send and receive while the other of the antennas 26 can be used for receive only, or one of the antennas 26 can be used as a backup for the other of the antennas 26.

As is obvious from FIGS. 11 and 17, the boards 6 and 7, and the cooling mechanism 23 are located at the thick second portion 3Bb of the housing 3B. Consequently, as an example, compared with the case in which the boards 6 and 7, and the cooling mechanism 23 are located at the thin first portion 3Ba, a larger space can easily be ensured, and thus, it is easier to obtain a cooling effect by air flows generated by the fan 24 of the cooling mechanism 23. In the present embodiment, the fan 24 and the heat radiation portion 23b are provided at the corner 3g where the end 3d is connected to the end 3c that is located on the upper side in the specified (controlled) in-use state. Therefore, as an example, the fan 24 and the heat radiation portion 23b can be arranged on the upper side in the housing 3B regardless of the in-use attitude of the electronic device 1B. Consequently, as an example, heat hardly accumulates in the housing 3B. Note that the fan 24 and the heat radiation portion 23b are provided adjacent to the exhaust port 22b.

The board 7 is provided at a location where the board 6 is interposed between the board 7 and the cooling mechanism 23 (at a location where the board 7, the board 6, and the cooling mechanism 23 are disposed in this order in the second portion 3Bb). With such a configuration, the air drawn from outside hits the board 7 before reaching the position of the board 6. Consequently, as an example, the board 7 is improved in heat radiation efficiency. The board 7 mounted with modules 8A and 8B is located on the side opposite to the cooling mechanism 23 which is another heavy object, relative to the board 6 which has a relatively large weight among components in the housing 3B and which is located in the middle of the housing 3B. Therefore, as an example, the electronic device 1B has a better weight balance. Consequently, as an example, the user can hold the electronic device 1B more easily when carrying it.

As illustrated in FIGS. 11 and 18, in the present embodiment, as an example, the wall 3m of the housing 3B is provided with an introduction port 22a2 near the fan 24, an introduction port 22a3 located on the side opposite to the introduction port 22a2 with the board 6 interposed therebetween, and the introduction port 22a1 that is located nearer the electronic components 12 as heat generating bodies than the introduction ports 22a2 and 22a3 are. Because the introduction port 22a2 is provided, air flows can be generated more efficiently in the housing 3B. An air flow S introduced from the introduction port 22a3 is divided into an air flow S2 that flows along a second surface 6b at the rear of the board 6 toward the fan 24, and an air flow S1 that passes through (wraps around, or detours around) the outside of an end 6c located on the side opposite to the fan 24 relative to the board 6 and flows along a first surface 6a in front of the board 6 toward the fan 24. Consequently, the electronic components (heat generating bodies) 12 provided on both sides of the first surface 6a and the second surface 6b of the board 6 can be cooled.

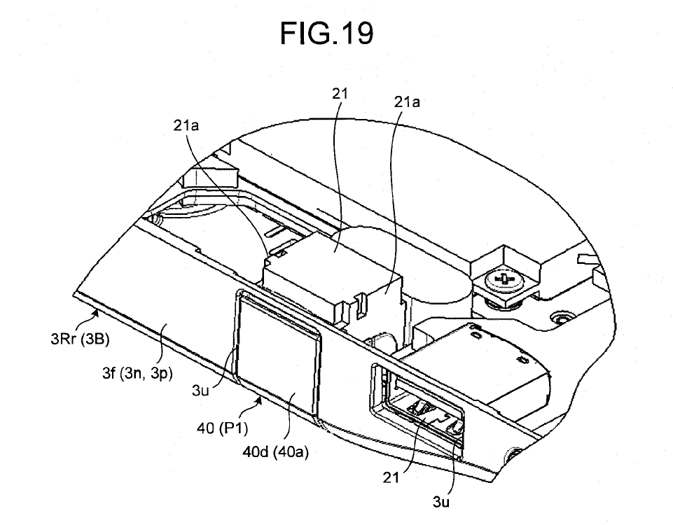

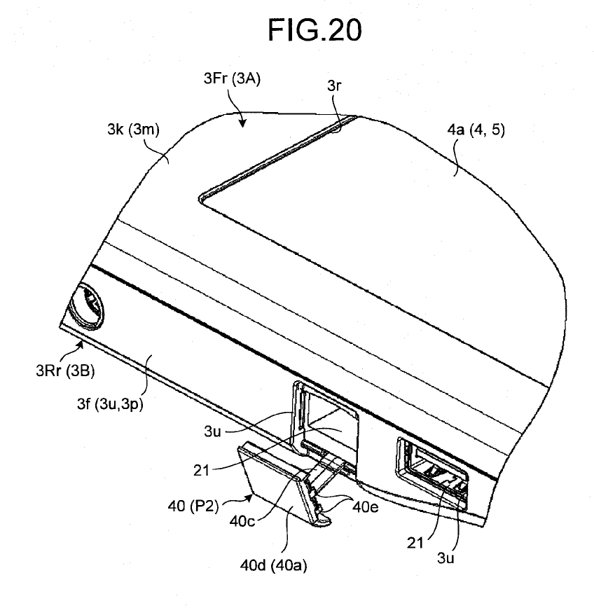

The electronic device 1B of the present embodiment also comprises the opening 3u, the connector 21, the lid 40, and the protrusions 50a and 50b which are the same as those of the first embodiment described above. That is, as an example, as illustrated in FIGS. 19 and 20, the lid 40 can move at least between the closed position P1 illustrated in FIG. 19 and the open position P2 illustrated in FIG. 20. In the present embodiment, as an example, the lid 40 is engaged with the housing 3B even in the open position P2. Consequently, the lid 40 is prevented from being lost by coming off from the housing 3B.

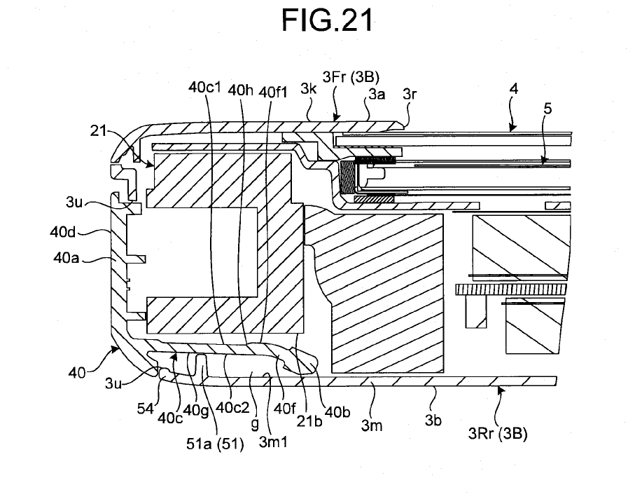

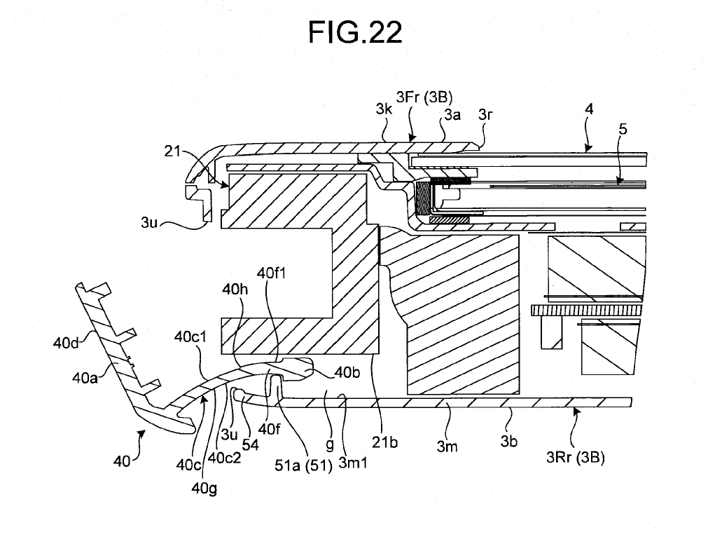

The electronic device 1B of the present embodiment also comprises the same configuration as that of the above-described first embodiment in which, as an example, the third portion 40c of the lid 40 is located between the connector 21 and the wall 3m (walls 51 and 54) of the housing 3B as illustrated in FIGS. 21 and 22. Consequently, with the present embodiment as well, the same effects as those of the above-described first embodiment can be obtained.

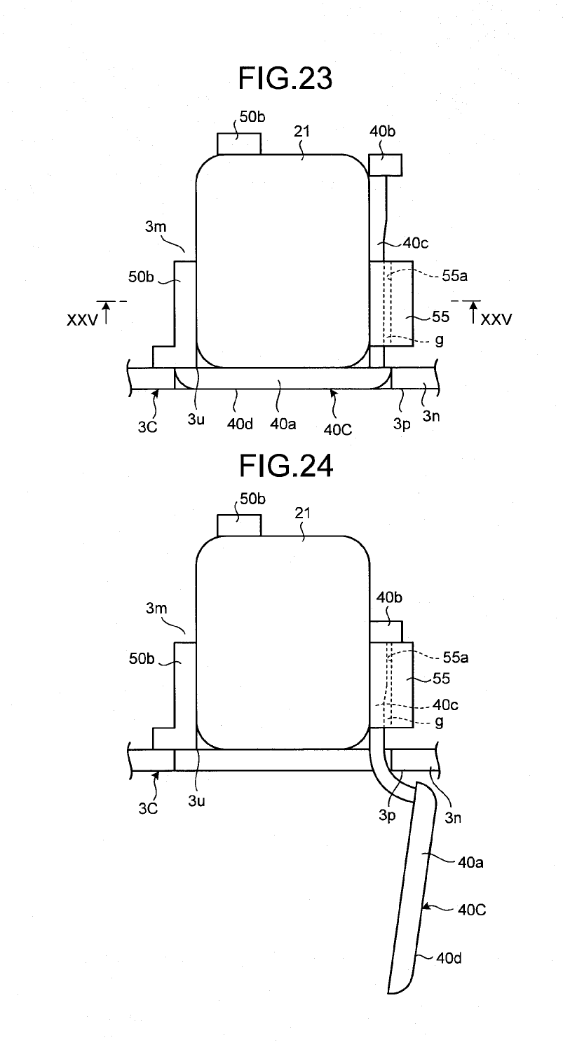

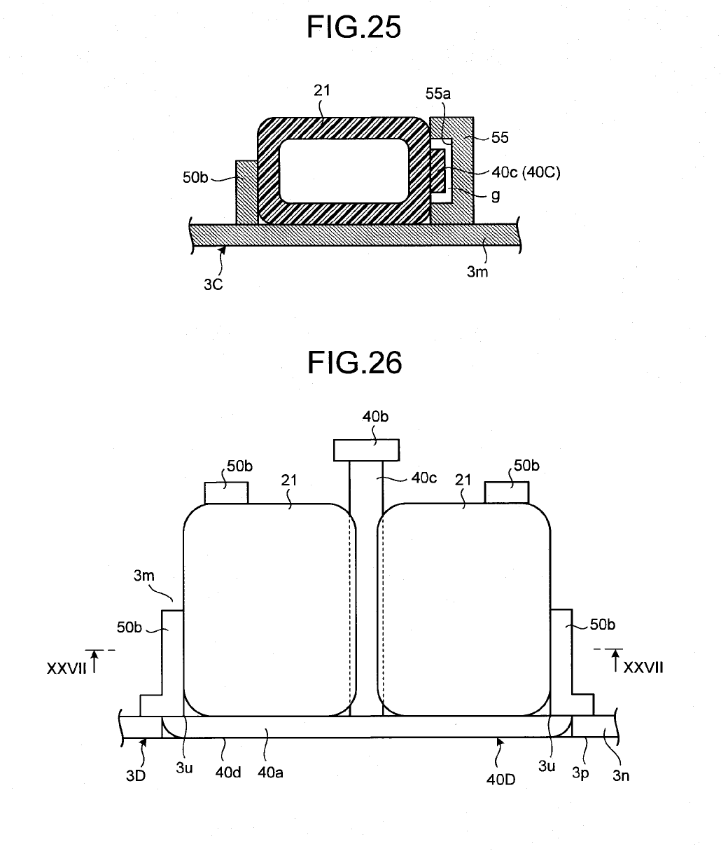

The embodiments have been described above. However, they are merely examples. Embodiments are not limited to the above-described ones, and various modifications are possible. For example, as illustrated in a first modification illustrated in FIGS. 23 to 25, a third portion 40c of a lid 40C can be located in a gap g between the connector 21 and (a recess 55a provided in) a wall 55 projecting from a wall 3m of a housing 3C. Also, as illustrated in FIG. 24, the lid 40C (first portion 40a) can open in a different direction relative to the wall 3m from the direction described in the first embodiment. As an example, the lid 40C can open in a direction along the wall 3m. The wall 55 can serve as the engaging portion, the first support, or the second support. According to the present variation, the same effects as those of the above-described embodiments can be obtained although the component and the portion surrounding the third portion 40c and suppressing or guiding the movement of the third portion 40c are different from those of the above-described embodiments.

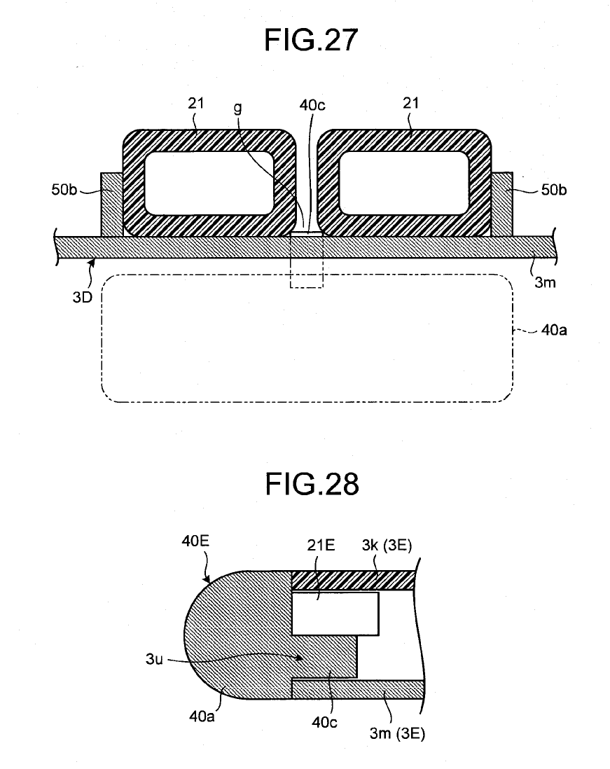

In addition, as illustrated in a second modification illustrated in FIGS. 26 and 27, a third portion 40c of a lid 40D can be located in a gap g between two connectors 21, 21 as well as between the two connectors 21, 21 and a wall 3m of a housing 3D. According to the present modification, the same effects as those of the embodiments and the modification described above can be obtained although the components and the portion surrounding the third portion 40c and suppressing or guiding the movement of the third portion 40c are different from those of the above-described embodiments and variation.

Moreover, as illustrated in a third modification illustrated in FIG. 28, the same effects can be obtained even with a configuration in which there is no portion or component corresponding to an engaging portion or a second portion. That is, a component 40E (module, such as a battery) detachably covers the opening 3u provided in a housing 3E. The component 40E comprises a first portion 40a and a third portion 40c. In addition, another component 21E (module, such as a connector) is located on an open end side or a rear side of the opening 3u. The component 21E constitutes at least a part of (a peripheral surface or a peripheral wall of) the opening 3u. According to the present modification, the same effects as those of the embodiments and the variations described above can be obtained although the component and the portion surrounding the third portion 40c and suppressing or guiding the movement of the third portion 40c are different from those of the above-described embodiments and variations. The technical features of the above-described embodiments can be combined as appropriate and put into practice. The specifications (such as structure, type, direction, shape, size, length, width, thickness, height, number, arrangement, position, and material) of each of the components can be changed as appropriate and put into practice.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a housing configured to house a display and at least a part of a connector, the housing comprising an engaging portion and an opening through which the connector is exposed; and
a lid comprising:
a first portion covering the opening;
a second portion located in the housing and configured to engage the engaging portion to prevent the second portion from moving out of the housing; and
a third portion between the first portion and the second portion, the third portion configured to move between a first position inside the housing and a second position outside the housing through a gap between the connector and the housing.

2. The television receiver of claim 1, further comprising a first support in the housing, wherein the first support is configured to support the connector and to prevent the third portion from moving in a direction intersecting a moving direction of the third portion.

3. The television receiver of claim 2, wherein the first support is relatively near the engaging portion.

4. The television receiver of claim 1, further comprising a second support in the housing, wherein the second support is configured to support the connector and wherein the second support comprises the engaging portion.

5. The television receiver of claim 1, wherein the third portion comprises a fourth portion relatively near the second portion and thicker than another portion of the third portion.

6. The television receiver of claim 5, wherein the third portion comprises a fifth portion that is thinner than the fourth portion.

7. The television receiver of claim 5, further comprising a third support configured to project from a wall of the housing and to support the third portion, wherein the fourth portion comprises a projection configured to project toward a side opposite the third support.

8. The television receiver of claim 7, further comprising a fourth support protruding from the wall to a position lower than the third support at a location nearer to an open end of the opening than the third support and configured to support the third portion.

9. An electronic device comprising:
a housing configured to house a display and at least a part of a component, the housing comprising an engaging portion and an opening through which the component is exposed; and
a lid comprising:
a first portion covering the opening;
a second portion located in the housing and configured to engage the engaging portion to prevent the second portion from moving out of the housing; and
a third portion between the first portion and the second portion and in a gap between the component and the housing.

10. An electronic device comprising:
a first component;
a housing with an opening through which the first component is exposed, the housing configured to house at least a part of the first component; and
a second component comprising:
a first portion on an outer side of the housing relative to the first component, the first portion configured to cover the opening; and
a second portion on an inner side of the housing relative to the portion, the second portion between the first component and the housing, wherein the second portion is configured to move between the first component and the housing.
